(19) United States
(12) Patent Application Publication
(10) Pub. No.: US 2025/0300142 A1
(43) Pub. Date: Sep. 25, 2025

(54) DISPLAY DEVICE, METHOD OF MANUFACTURING THE SAME, AND ELECTRONIC DEVICE

(71) Applicant: SAMSUNG DISPLAY CO., LTD., Yongin-si (KR)

(72) Inventor: BYUNGKYU SON, Yongin-si (KR)

(21) Appl. No.: 19/009,537

(22) Filed: Jan. 3, 2025

(30) Foreign Application Priority Data
Mar. 19, 2024 (KR) 10-2024-0037796

(51) Int. Cl. H01L 25/075; G09G 3/00; H10H 29/80

(52) U.S. Cl. CPC H01L 25/0753; G09G 3/006; H10H 29/942; G09G 2330/12

(57) ABSTRACT

A display device includes a substrate including a display area and a non-display area adjacent to the display area, a light emitting element disposed in the display area of the substrate and including a first light emitting layer and a second light emitting layer disposed on the first light emitting layer, and an inspection array disposed in the non-display area of the substrate and including a first inspection pattern and a second inspection pattern disposed on the first inspection pattern.

### CROSS-REFERENCE TO RELATED APPLICATION(S)

This application claims priority under 35 USC § 119 to Korean Patent Application No. 10-2024-0037796 filed on Mar. 19, 2024, in the Korean Intellectual Property Office (KIPO), the entire disclosure of which is incorporated by reference herein.

### BACKGROUND

### 1. Field

The present disclosure relates to a display device, more particularly, to a display device that provides visual information, a method of manufacturing the display device, and an electronic device including the display device.

### 2. Description of the Related Art

A display device is formed by laminating a plurality of layers such as a light emitting layer, a metal layer, or the like. In order to form the plurality of layers of the display device, a deposition process of depositing various types of thin films may be performed. The deposition process may be performed by closely contacting a mask defining an opening having the same pattern as a deposition pattern of the light emitting layer, the metal layer, or the like on a target substrate on which deposition is to be performed. The deposition pattern may be formed in an area exposed by the opening, and a shape of the deposition pattern may be controlled depending on a shape of the opening.

Meanwhile, the display device includes a light emitting element, and the light emitting element includes a pixel electrode, a common electrode, and a light emitting layer disposed between the pixel electrode and the common electrode. In order to improve luminous efficiency of the light emitting element, functional layers (e.g., a hole transport layer, an electron transport layer, an auxiliary layer, or the like) may be further disposed above and below the light emitting layer.

### SUMMARY

Embodiments provide a display device with improved reliability.

Embodiments provide a method of manufacturing the display device.

Embodiments provide an electronic device including the display device.

A display device according to an embodiment of the present disclosure includes a substrate including a display area and a non-display area adjacent to the display area, a light emitting element disposed in the display area of the substrate and including a first light emitting layer and a second light emitting layer disposed on the first light emitting layer, and an inspection array disposed in the non-display area of the substrate and including a first inspection pattern and a second inspection pattern disposed on the first inspection pattern.

In an embodiment, the first light emitting layer and the first inspection pattern may include a same material, and the second light emitting layer and the second inspection pattern may include a same material.

In an embodiment, the first light emitting layer and the second light emitting layer may overlap in a plan view.

In an embodiment, the first inspection pattern and the second inspection pattern may overlap in a plan view.

In an embodiment, the first light emitting layer and the second light emitting layer may include a same material.

In an embodiment, the display device may further include a charge generation layer disposed between the first light emitting layer and the second light emitting layer and between the first inspection pattern and the second inspection pattern. The charge generation layer may include a first semiconductor layer doped with n-type dopants and a second semiconductor layer doped with p-type dopants.

In an embodiment, the charge generation layer may extend from the display area to the non-display area.

In an embodiment, the light emitting element may include a first light emitting element that emits first light and includes a first first light emitting layer and a first second light emitting layer disposed on the first first light emitting layer, a second light emitting element that emits second light and includes a second first light emitting layer and a second second light emitting layer disposed on the second first light emitting layer, and a third light emitting element that emits third light and includes a third first light emitting layer and a third second light emitting layer disposed on the third first light emitting layer.

In an embodiment, the inspection array may include a first inspection array including a first first inspection pattern including a same material as the first first light emitting layer and a first second inspection pattern disposed on the first first inspection pattern and including a same material as the first second light emitting layer, a second inspection array including a second first inspection pattern including a same material as the second first light emitting layer and a second second inspection pattern disposed on the second first inspection pattern and including a same material as the second second light emitting layer, and a third inspection array including a third first inspection pattern including a same material as the third first light emitting layer and a third second inspection pattern disposed on the third first inspection pattern and including a same material as the third second light emitting layer.

In an embodiment, the second inspection array may be adjacent to the first inspection array in one direction, and the third inspection array may be adjacent to the second inspection array in the one direction.

A method of manufacturing a display device according to an embodiment of the present disclosure includes forming a first light emitting layer in a display area on a substrate and a first inspection pattern in a non-display area adjacent to the display area on the substrate using a plurality of masks, and forming a second light emitting layer on the first light emitting layer and a second inspection pattern on the first inspection pattern using the plurality of masks.

In an embodiment, the first light emitting layer and the first inspection pattern may be formed of a same material, and the second light emitting layer and the second inspection pattern may be formed of a same material.

In an embodiment, the first light emitting layer and the second light emitting layer may be formed to overlap in a plan view, and the first inspection pattern and the second inspection pattern may be formed to overlap in the plan view.

In an embodiment, the first light emitting layer and the second light emitting layer may be formed of a same material.

In an embodiment, the method may further include forming a charge generation layer on the first light emitting layer and the first inspection pattern using an open mask defining an opening corresponding to the display area and the non-display area, after the forming of the first light emitting layer and the first inspection pattern and before the forming of the second light emitting layer and the second inspection pattern.

In an embodiment, the method may further include measuring the first inspection pattern to confirm alignment of the first light emitting layer and measuring the second inspection pattern to confirm alignment of the second light emitting layer after the forming of the second light emitting layer and the second inspection pattern.

In an embodiment, the forming of the first light emitting layer and the first inspection pattern may include forming a first first light emitting layer and a first first inspection pattern using a first mask among the plurality of masks, forming a second first light emitting layer and a second first inspection pattern using a second mask among the plurality of masks, and forming a third first light emitting layer and a third first inspection pattern using a third mask among the plurality of masks.

In an embodiment, the first first light emitting layer and the first first inspection pattern may be formed of a material that emits first light, the second first light emitting layer and the second first inspection pattern may be formed of a material that emits second light, and the third first light emitting layer and the third first inspection pattern may be formed of a material that emits third light.

In an embodiment, the forming of the second light emitting layer and the second inspection pattern may include forming a first second light emitting layer on the first first light emitting layer and a first second inspection pattern on the first first inspection pattern using the first mask, forming a second second light emitting layer on the second first light emitting layer and a second second inspection pattern on the second first inspection pattern using the second mask, and forming a third second light emitting layer on the third first light emitting layer and a third second inspection pattern on the third first inspection pattern using the third mask.

In an embodiment, the first second light emitting layer and the first second inspection pattern may be formed of a material that emits first light, the second second light emitting layer and the second second inspection pattern may be formed of a material that emits second light, and the third second light emitting layer and the third second inspection pattern may be formed of a material that emits third light.

An electronic device according to an embodiment of the present disclosure includes a display device and a power module that supplies power to the display device. The display device includes a substrate including a display area and a non-display area adjacent to the display area, a light emitting element disposed in the display area of the substrate and including a first light emitting layer and a second light emitting layer disposed on the first light emitting layer, and an inspection array disposed in the non-display area of the substrate and including a first inspection pattern and a second inspection pattern disposed on the first inspection pattern.

In a display device according to embodiments of the present disclosure, the display device may include first and second light emitting layers overlapping in a plan view in a display area, and first and second inspection patterns overlapping in a plan view in a non-display area and used to confirm alignment of the first and second light emitting layers, respectively. The first and second light emitting layers and the first and second inspection patterns may be formed using the same mask. Since different layers may be formed using one mask, a burden on mask management, design, or the like may be minimized, and an area in which the first and second inspection patterns are disposed in the non-display area may be reduced.

### BRIEF DESCRIPTION OF THE DRAWINGS

FIG. 1 is a plan view illustrating a display device according to an embodiment of the present disclosure.

FIG. 2 is a cross-sectional view taken along line I-I′ of FIG. 1 according to an embodiment of the present disclosure.

FIG. 3 is an enlarged plan view of area A of FIG. 1 according to an embodiment of the present disclosure.

FIG. 4 is a cross-sectional view taken along line II-II′ of FIG. 3 according to an embodiment of the present disclosure.

FIGS. 5A, 5B, 6A, 6B, 7A, 7B, 8A, and 8B are views illustrating a method of manufacturing a display device according to an embodiment of the present disclosure.

FIG. 9 is a perspective view schematically illustrating a mask used in a method of manufacturing a display device according to an embodiment of the present disclosure.

FIG. 10 is a block diagram illustrating an electronic device according to an embodiment of the present disclosure.

FIG. 11 is a schematic view illustrating electronic devices according to embodiments of the present disclosure.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

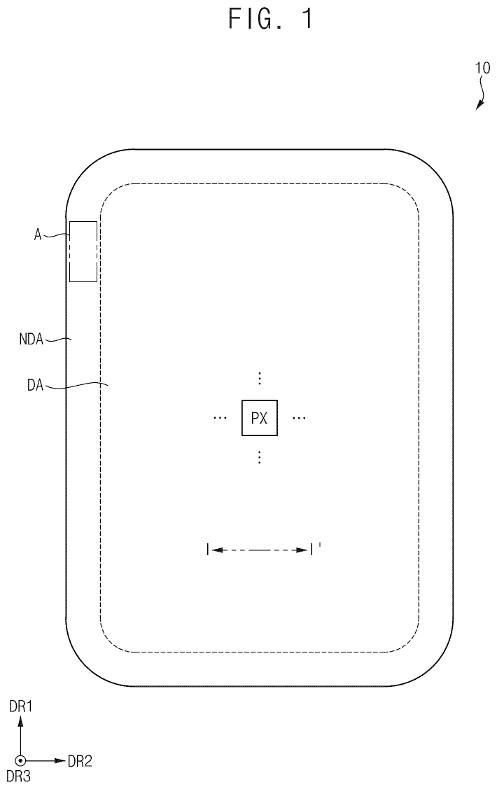

FIG. 1 is a plan view illustrating a display device according to an embodiment of the present disclosure.

Referring to FIG. 1, a display device 10 according to an embodiment of the present disclosure may include a display area DA and a non-display area NDA.

The display area DA may be an area that displays an image. A plurality of pixels PX may be disposed in the display area DA and repeatedly arranged along a first direction DR1 and a second direction DR2 intersecting the first direction DR1 in a plan view. For example, the second direction DR2 may be perpendicular to the first direction DR1. Each of the pixels PX may be defined as a minimum light emitting unit that displays light.

Signal lines such as gate lines, data lines, or the like may be disposed in the display area DA. The signal lines may be connected to each of the pixels PX. Each of the pixels PX may receive gate signals, data signals, or the like from the signal lines. Accordingly, an image may be displayed in a third direction DR3 intersecting each of the first direction DR1 and the second direction DR2 in the display area DA. For example, the third direction DR3 may be perpendicular to each of the first direction DR1 and the second direction DR2.

The non-display area NDA may be an area that does not display an image. The non-display area NDA may be disposed around the display area DA. For example, the non-display area NDA may surround the display area DA in a plan view. Drivers for displaying an image of the display area DA may be disposed in the non-display area NDA.

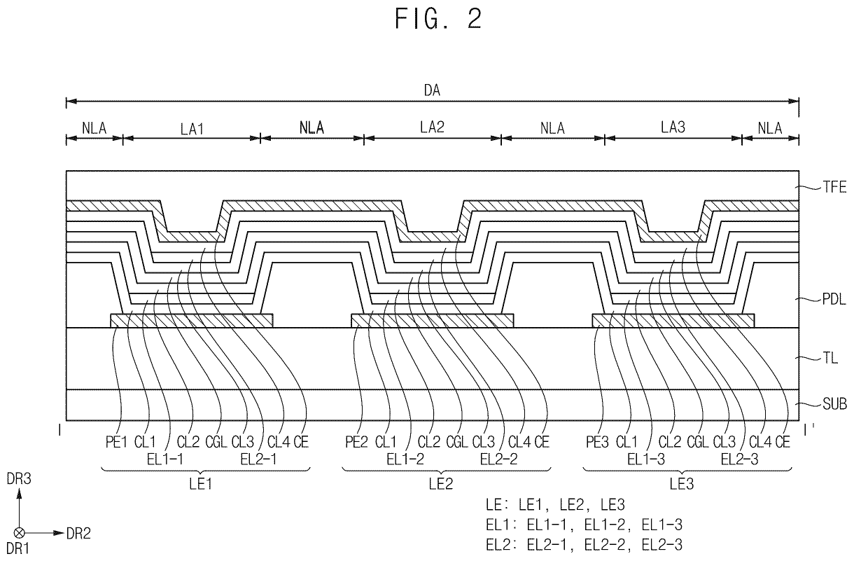

FIG. 2 is a cross-sectional view taken along line I-I′ of FIG. 1. For example, FIG. 2 may be a cross-sectional view of a portion of an example of the display area DA.

Referring to FIGS. 1 and 2, the display device 10 may include a substrate SUB, a circuit layer TL, a light emitting element LE, a pixel defining layer PDL, and an encapsulation layer TFE.

The substrate SUB may include a transparent material or an opaque material. Examples of materials that may be used as the substrate SUB may include polyimide, quartz, glass, or the like. These may be used alone or in combination with each other. In an embodiment, the first direction DR1 and the second direction DR2 may be parallel to an upper surface of the substrate SUB, and the third direction DR3 may be perpendicular to the upper surface of the substrate SUB.

The circuit layer TL may be disposed on the substrate SUB. The circuit layer TL may include a transistor, a capacitor, or the like. The circuit layer TL may include an insulating layer, a semiconductor pattern, a conductive pattern, and a signal line. A preliminary insulating layer, a semiconductor layer, and a conductive layer may be formed on the substrate SUB through processes such as coating, deposition, or the like, and the preliminary insulating layer, the semiconductor layer, and the conductive layer may be selectively patterned through a plurality of photolithography processes. Thereafter, the insulating layer, the semiconductor pattern, the conductive pattern, and the signal line included in the circuit layer TL may be formed.

The light emitting element LE and the pixel defining layer PDL may be disposed on the circuit layer TL.

The light emitting element LE may include a first light emitting element LE1, a second light emitting element LE2, and a third light emitting element LE3, and may include a pixel electrode PE, a first common layer CL1, a first light emitting layer EL1, a second common layer CL2, a charge generation layer CGL, a third common layer CL3, a second light emitting layer EL2, and a fourth common layer CL4, a common electrode CE. The first light emitting layer EL1 may include a first first light emitting layer EL1-1 (hereinafter, will be referred to as “(1-1)th light emitting layer”), a second first light emitting layer EL1-2 (hereinafter, will be referred to as “(1-2)th light emitting layer”), and a third first light emitting layer EL1-3 (hereinafter, will be referred to as “(1-3)th light emitting layer”). The second light emitting layer EL2 may include a first second light emitting layer EL2-1 (hereinafter, will be referred to as “(2-1)th light emitting layer”), a second second light emitting layer EL2-2 (hereinafter, will be referred to as “(2-2)th light emitting layer”), and a third second light emitting layer EL2-3 (hereinafter, will be referred to as “(2-3)th light emitting layer”). The pixel electrode PE may include a first pixel electrode PE1, a second pixel electrode PE2, and a third pixel electrode PE3.

Specifically, the first light emitting element LE1 may include the first pixel electrode PE1, the first common layer CL1, the (1-1)th light emitting layer EL1-1, the second common layer CL2, the charge generation layer CGL, the third common layer CL3, the (2-1)th light emitting layer EL2-1, the fourth common layer CL4, and the common electrode CE. The second light emitting element LE2 may include the second pixel electrode PE2, the first common layer CL1, the (1-2)th light emitting layer EL1-2, the second common layer CL2, the charge generation layer CGL, the third common layer CL3, the (2-2)th light emitting layer EL2-2, the fourth common layer CL4, and the common electrode CE. The third light emitting element LE3 may include the third pixel electrode PE3, the first common layer CL1, the (1-3)th light emitting layer EL1-3, the second common layer CL2, the charge generation layer CGL, the third common layer CL3, the (2-3)th light emitting layer EL2-3, the fourth common layer CL4, and the common electrode CE.

The first pixel electrode PE1, the second pixel electrode PE2, and the third pixel electrode PE3 may be disposed on the circuit layer TL. Each of the first, second, and third pixel electrodes PE1, PE2, and PE3 may be electrically connected to a corresponding transistor included in the circuit layer TL. The first, second, and third pixel electrodes PE1, PE2, and PE3 may include a metal, an alloy, a conductive metal nitride, a conductive metal oxide, a transparent conductive material, or the like. These may be used alone or in combination with each other.

The pixel defining layer PDL may expose at least a center portion of an upper surface of each of the first, second, and third pixel electrodes PE1, PE2, and PE3. For example, the pixel defining layer PDL may cover a side surface of each of the first, second, and third pixel electrodes PE1, PE2, and PE3. In an embodiment, the pixel defining layer PDL may cover an edge portion of the upper surface of each of the first to third pixel electrodes PE1 to PE3. The pixel defining layer PDL may include an organic material such as a polyimide resin, an epoxy resin, and a siloxane resin, or an inorganic material such as silicon oxide, silicon nitride, and silicon oxynitride. These may be used alone or in combination with each other. In an embodiment, each of the first to third light emitting elements LE1 to LE3 may share the first common layer CL1, the second common layer CL2, the charge generation layer CGL, the third common layer CL3, the fourth common layer CL4, and the common electrode CE. Each of the first common layer CL1, the second common layer CL2, the charge generation layer CGL, the third common layer CL3, the fourth common layer CL4, and the common electrode CE may continuously extend on the upper surface of the substrate SUB to be disposed in each of the first to third light emitting elements LE1 to LE3. In an embodiment, the first to third pixel electrodes PE1 to PE3 may be separated from each other and disposed in the first to third light emitting elements LEI to LE3, respectively. In an embodiment, the light emitting layers EL1-1, EL1-2, and EL1-3 may be separated from each other and disposed in the first light emitting element LE1, the second light emitting element LE2, and the third light emitting element LE3, respectively. In an embodiment, the light emitting layers EL2-1, EL2-2, and EL2-3 may be separated from each other and disposed in the first light emitting element LE1, the second light emitting element LE2, and the third light emitting element LE3, respectively.

A non-light emitting area NLA may be defined corresponding to an area in which the pixel defining layer PDL is disposed. In addition, a first light emitting area LA1, a second light emitting area LA2, and a third light emitting area LA3 may be defined corresponding to areas of the first, second, and third pixel electrodes PE1, PE2, and PE3 exposed by the pixel defining layer PDL, respectively. That is, the non-light emitting area NLA may overlap the pixel defining layer PDL in a plan view, and the first, second, and third light emitting areas LA1, LA2, and LA3 may overlap the first, second, and third light emitting elements LE1, LE2, and LE3 in a plan view, respectively. The non-light emitting area NLA may be defined between the first, second, and third light emitting areas LA1, LA2, and LA3.

The first, second, and third light emitting areas LA1, LA2, and LA3 may emit light in different wavelength bands. The first light emitting area LA1 may emit first light, the second light emitting area LA2 may emit second light, and the third light emitting area LA3 may emit third light. For example, the first light may be light in a blue wavelength band, the second light may be light in a green wavelength band, and the third light may be light in a red wavelength band, but the present disclosure is not limited thereto. For example, the first light may be light in a wavelength band of about 400 nanometers (nm) to about 495 nm, the second light may be light in a wavelength band of about 495 nm to about 580 nm, and the third light may be light in a wavelength band of about 580 nm to about 780 nm, but the present disclosure is not limited thereto.

The first common layer CL1 may be disposed on the pixel electrode and the pixel defining layer PDL. The first common layer CL1 may have a single-layer structure or a multi-layer structure. For example, the first common layer CL1 may include at least one of a hole injection layer (HIL) and a hole transport layer (HTL).

The first light emitting layer EL1 may be disposed on the first common layer CL1. The (1-1)th, (1-2)th, and (1-3)th light emitting layers EL1-1, EL1-2, and EL1-3 may overlap the first, second, and third light emitting areas LA1, LA2, and LA3 in a plan view, respectively. The (1-1)th light emitting layer EL1-1 may be disposed on the first pixel electrode PE1 exposed by the pixel defining layer PDL, the (1-2)th light emitting layer EL1-2 may be disposed on the second pixel electrode PE2 exposed by the pixel defining layer PDL, and the (1-3)th light emitting layer EL1-3 may be disposed on the third pixel electrode PE3 exposed by the pixel defining layer PDL.

In an embodiment, the (1-1)th, (1-2)th, and (1-3)th light emitting layers EL1-1, EL1-2, and EL1-3 may emit light in different wavelength bands. The (1-1)th light emitting layer EL1-1 may emit the first light, and may include a material that emits the first light. The (1-2)th light emitting layer EL1-2 may emit the second light, and may include a material that emits the second light. The (1-3)th light emitting layer EL1-3 may emit the third light, and may include a material that emits the third light.

However, the present disclosure is not limited thereto. In an embodiment, the (1-1)th, (1-2)th, and (1-3)th light emitting layers EL1-1, EL1-2, and EL1-3 may emit light in the same wavelength band, or at least one of the (1-1)th, (1-2)th, and (1-3)th light emitting layers EL1-1, EL1-2, and EL1-3 may emit light in different wavelength bands from the other light emitting layers. For example, the (1-1)th, (1-2)th, and (1-3)th light emitting layers EL1-1, EL1-2, and EL1-3 may include a first light emitting layer that emits light in a blue wavelength band and a second light emitting layer that emits light in a green wavelength band, and in this case, the display device 10 may further include a color panel that transmits light emitted from the (1-1)th, (1-2)th, and (1-3)th light emitting layers EL1-1, EL1-2, and EL1-3 or converts the light into light in different wavelength bands.

The second common layer CL2 may be disposed on the first common layer CL1 and the first light emitting layer EL1. For example, the second common layer CL2 may include an electron transport layer (ETL).

The charge generation layer CGL may be disposed on the second common layer CL2. The charge generation layer CGL may extend from the display area DA to the non-display area NDA. For example, the charge generation layer CGL may include an n-type charge generation layer that provides an electron to the first light emitting layer EL1 and a p-type charge generation layer that provides a hole to the second light emitting layer EL2. In an embodiment, the n-type charge generation layer may include a first semiconductor layer doped with n-type impurities and contacting the second common layer CL2, and the p-type charge generation layer may include a second semiconductor layer doped with p-type impurities and contacting the third common layer CL3. The n-type charge generation layer and the p-type charge generation layer may form a P-N junction at an interface therebetween, and the second common layer CL2 and the third common layer CL3 may be biased with a positive voltage and a negative voltage, respectively, so that electrons are supplied to the first light emitting layer EL1 via the second common layer CL2, and holes are supplied to the second light emitting layer EL2 via the third common layer CL3.

The third common layer CL3 may be disposed on the charge generation layer CGL. For example, the third common layer CL3 may include a hole transport layer.

The second light emitting layer EL2 may be disposed on the third common layer CL3. The (2-1)th, (2-2)th, and (2-3)th light emitting layers EL2-1, EL2-2, and EL2-3 may overlap the first, second, and third light emitting areas LA1, LA2, and LA3 in a plan view, respectively. The (2-1)th, (2-2)th, and (2-3)th light emitting layers EL2-1, EL2-2, and EL2-3 may overlap the (1-1)th, (1-2)th, and (1-3)th light emitting layers EL1-1, EL1-2, and EL1-3 in a plan view, respectively. The (2-1)th light emitting layer EL2-1 may be disposed on the first pixel electrode PE1 exposed by the pixel defining layer PDL, the (2-2)th light emitting layer EL2-2 may be disposed on the second pixel electrode PE2 exposed by the pixel defining layer PDL, and the (2-3)th light emitting layer EL2-3 may be disposed on the third pixel electrode PE3 exposed by the pixel defining layer PDL.

In an embodiment, the (2-1)th, (2-2)th, and (2-3)th light emitting layers EL2-1, EL2-2, and EL2-3 may emit light in different wavelength bands. For example, the (2-1)th, (2-2)th, and (2-3)th light emitting layers EL2-1, EL2-2, and EL2-3 may emit light in the same wavelength band as the (1-1)th, (1-2)th, and (1-3)th light emitting layers EL1-1, EL1-2, and EL1-3, respectively. In this case, the (2-1)th, (2-2)th, and (2-3)th light emitting layers EL2-1, EL2-2, and EL2-3 may include the same material as the (1-1)th, (1-2)th, and (1-3)th light emitting layers EL1-1, EL1-2, and EL1-3, respectively. The (2-1)th light emitting layer EL2-1 may emit the first light, and may include a material that emits the first light. The (2-2)th light emitting layer EL2-2 may emit the second light, and may include a material that emits the second light. The (2-3)th light emitting layer EL2-3 may emit the third light, and may include a material that emits the third light. In an embodiment, the (2-1)th, (2-2)th, and (2-3)th light emitting layers EL2-1, EL2-2, and EL2-3 may emit light in different wavelength bands from the (1-1)th, (1-2)th, and (1-3)th light emitting layers EL1-1, EL1-2, and EL1-3, respectively. In this case, the (2-1)th, (2-2)th, and (2-3)th light emitting layers EL2-1, EL2-2, and EL2-3 may include different materials from the (1-1)th, (1-2)th, and (1-3)th light emitting layers EL1-1, EL1-2, and EL1-3, respectively.

However, the present disclosure is not limited thereto. In an embodiment, the (2-1)th, (2-2)th, and (2-3)th light emitting layers EL2-1, EL2-2, and EL2-3 may emit light in the same wavelength band, or at least one of the (2-1)th, (2-2)th, and (2-3)th light emitting layers EL2-1, EL2-2, and EL2-3 may emit light in different wavelength bands. For example, the (2-1)th, (2-2)th, and (2-3)th light emitting layers EL2-1, EL2-2, and EL2-3 may include a first light emitting layer that emits light in a blue wavelength band and a second light emitting layer that emits light in a green wavelength band, and in this case, the display device 10 may further include a color panel that transmits light emitted from the (2-1)th, (2-2)th, and (2-3)th light emitting layers EL2-1, EL2-2, and EL2-3 or converts the light into light in different wavelength bands.

The fourth common layer CL4 may be disposed on the third common layer CL3 and the second light emitting layer EL2. The fourth common layer CL4 may have a single-layer structure or a multi-layer structure. For example, the fourth common layer CL4 may include at least one of an electron injection layer (EIL) and an electron transport layer.

The common electrode CE may be disposed on the fourth common layer CL4. The common electrode CE may overlap the first, second, and third light emitting areas LA1, LA2, and LA3 and the non-light emitting area NLA. That is, the common electrode CE may continuously extend in the first, second, and third light emitting areas LA1, LA2, and LA3 and the non-light emitting area NLA. The common electrode CE may include a metal, an alloy, a conductive metal oxide, a conductive metal nitride, a transparent conductive material, or the like. These may be used alone or in combination with each other.

Accordingly, the first light emitting element LE1 including the first pixel electrode PE1, the first, second, third, and fourth common layers CL1, CL2, CL3, and CL4, the (1-1)th and (2-1)th light emitting layers EL1-1 and EL2-1, the charge generation layer CGL, and the common electrode CE may be disposed in the first light emitting area LA1 on the substrate SUB. The second light emitting element LE2 including the second pixel electrode PE2, the first, second, third, and fourth common layers CL1, CL2, CL3, and CL4, the (1-2)th and (2-2)th light emitting layers EL1-2 and EL2-2, the charge generation layer CGL, and the common electrode CE may be disposed in the second light emitting area LA2 on the substrate SUB. The third light emitting element LE3 including the third pixel electrode PE3, the first, second, third, and fourth common layers CL1, CL2, CL3, and CL4, the (1-3)th and (2-3)th light emitting layers EL1-3 and EL2-3, the charge generation layer CGL, and the common electrode CE may be disposed in the third light emitting area LA3 on the substrate SUB. The first, second, and third light emitting elements LE1, LE2, and LE3 may correspond to the pixels PX, respectively. For example, the first light emitting element LE1 may emit the first light, the second light emitting element LE2 may emit the second light, and the third light emitting element LE3 may emit the third light.

The encapsulation layer TFE may be disposed on the common electrode CE. The encapsulation layer TFE may prevent impurities, moisture, outside air, or the like from penetrating into the light emitting element LE from the outside. The encapsulation layer TFE may include at least one inorganic encapsulation layer and at least one organic encapsulation layer.

Although FIG. 2 illustrates that the light emitting element LE includes a structure in which two light emitting layers are stacked, the present disclosure is not limited thereto. In an embodiment, the light emitting element LE may include a structure in which a single light emitting layer is disposed or three or more light emitting layers are stacked.

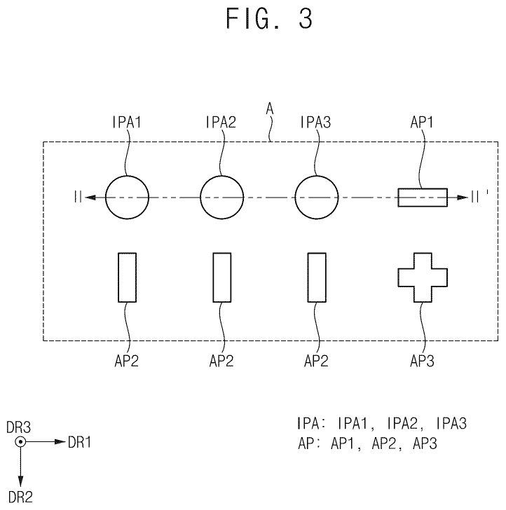

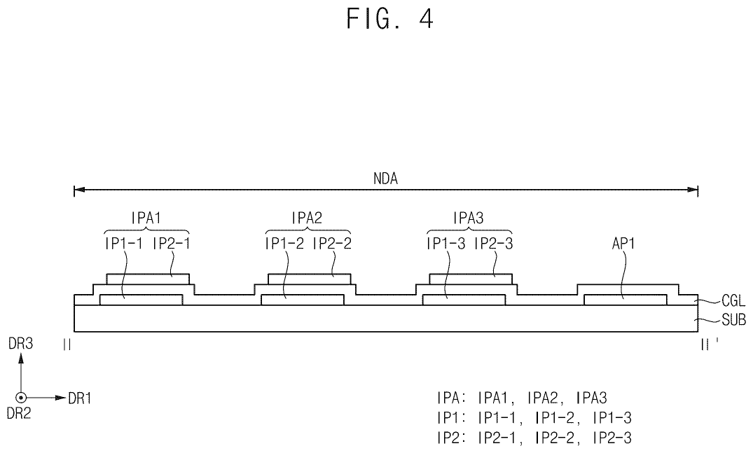

FIG. 3 is an enlarged plan view of area A of FIG. 1. FIG. 4 is a cross-sectional view taken along line II-II′ of FIG. 3. For example, FIGS. 3 and 4 may be an enlarged plan view and a cross-sectional view of a portion of an example of the non-display area NDA, respectively.

Referring to FIGS. 1, 2, 3, and 4, the display device 10 may include the substrate SUB, an inspection array IPA, an alignment pattern AP, and the charge generation layer CGL.

The inspection array IPA and the alignment pattern AP may be disposed in the non-display area NDA on the substrate SUB. In this case, the inspection array IPA and the alignment pattern AP are disposed in the non-display area NDA. However, the positions of the inspection array IPA and the alignment pattern AP are not limited thereto.

The inspection array IPA may include a first inspection array IPA1, a second inspection array IPA2, and a third inspection array IPA3, and may include a first inspection pattern IP1 and a second inspection pattern IP2. The first inspection pattern IP1 may include a first first inspection pattern IP1-1 (hereinafter, will be referred to as “(1-1)th inspection pattern”), a second first inspection pattern IP1-2 (hereinafter, will be referred to as “(1-2)th inspection pattern”), and a third first inspection pattern IP1-3 (hereinafter, will be referred to as “(1-3)th inspection pattern”), and the second inspection pattern IP2 may include a first second inspection pattern IP2-1 (hereinafter, will be referred to as “(2-1)th inspection pattern”), a second second inspection pattern IP2-2 (hereinafter, will be referred to as “(2-2)th inspection pattern”), and a third second inspection pattern IP2-3 (hereinafter, will be referred to as “(2-3)th inspection pattern”).

Specifically, the first inspection array IPA1 may include the (1-1)th inspection pattern IP1-1 and the (2-1)th inspection pattern IP2-1, the second inspection array IPA2 may include the (1-2)th inspection pattern IP1-2 and the (2-2)th inspection pattern IP2-2, and the third inspection array IPA3 may include the (1-3)th inspection pattern IP1-3 and the (2-3)th inspection pattern IP2-3.

The first, second, and third inspection arrays IPA1, IPA2, and IPA3 may be arranged in one direction. For example, the second inspection array IPA2 may be adjacent to the first inspection array IPA1 in the first direction DR1, and the third inspection array IPA3 may be adjacent to the second inspection array IPA2 in the first direction DR1. However, the present disclosure is not limited thereto, and the arrangement of the first, second, and third inspection arrays IPA1, IPA2, and IPA3 may be variously modified.

The first inspection array IPA1 may be disposed in the non-display area NDA to confirm alignment of a light emitting layer of the first light emitting element LE1. For example, the first inspection array IPA1 may be utilized to determine if the light emitting layer of the first light emitting element LE1 is deposited in the desired location. In other words, by measuring the position of the first inspection array IPA1, it can be assessed whether the light emitting layer is deposited in the desired location. For example, the inspection of the first inspection array IPA1 being disposed at a target position may indicate whether the light emitting layer is disposed at a target position. The first inspection array IPA1 may include the same material as the light emitting layer of the first light emitting element LE1. In an embodiment, the first inspection array IPA1 and the light emitting layer of the first light emitting element LE1 may be consisted of the same material.

The first inspection array IPA1 may include the (1-1)th inspection pattern IP1-1 and the (2-1)th inspection pattern IP2-1 disposed on the (1-1)th inspection pattern IP1-1. The (1-1)th inspection pattern IP1-1 and the (2-1)th inspection pattern IP2-1 may overlap in a plan view. For example, the (1-1)th inspection pattern IP1-1 and the (2-1)th inspection pattern IP2-1 may partially overlap in a plan view. The (1-1)th inspection pattern IP1-1 may be a pattern for confirming alignment of the (1-1)th light emitting layer EL1-1, and the (2-1)th inspection pattern IP2-1 may be a pattern for confirming alignment of the (2-1)th light emitting layer EL2-1. For example, the (1-1)th inspection pattern IP1-1 may be utilized to determine if the (1-1)th light emitting layer EL1-1 is deposited in the desired location. In other words, by measuring the position of the (1-1)th inspection pattern IP1-1, it can be assessed whether the (1-1)th light emitting layer EL1-1 is deposited in the desired location. Similarly, the (2-1)th inspection pattern IP2-1 may be utilized to determine if the (2-1)th light emitting layer EL2-1 is deposited in the desired location. In other words, by measuring the position of the (2-1)th inspection pattern IP2-1, it can be assessed whether the (2-1)th light emitting layer EL2-1 is deposited in the desired location. In an embodiment, the (1-1)th inspection pattern IP1-1 may include the same material as the (1-1)th light emitting layer EL1-1, and the (2-1)th inspection pattern IP2-1 may include the same material as the (2-1)th light emitting layer EL2-1. In an embodiment, the (1-1)th inspection pattern IP1-1 and the (1-1)th light emitting layer EL1-1 may be consisted of the same material, and the (2-1)th inspection pattern IP2-1 and the (2-1)th light emitting layer EL2-1 may be consisted of the same material.

The second inspection array IPA2 may be disposed in the non-display area NDA to confirm alignment of a light emitting layer of the second light emitting element LE2. For example, the second inspection array IPA2 may be utilized to determine if the light emitting layer of the second light emitting element LE2 is deposited in the desired location. In other words, by measuring the position of the second inspection array IPA2, it can be assessed whether the light emitting layer is deposited in the desired location. The second inspection array IPA2 may include the same material as the light emitting layer of the second light emitting element LE2. In an embodiment, the second inspection array IPA2 and the light emitting layer of the second light emitting element LE2 may be consisted of the same material.

The second inspection array IPA2 may include the (1-2)th inspection pattern IP1-2 and the (2-2)th inspection pattern IP2-2 disposed on the (1-2)th inspection pattern IP1-2. The (1-2)th inspection pattern IP1-2 and the (2-2)th inspection pattern IP2-2 may overlap in a plan view. For example, the (1-2)th inspection pattern IP1-2 and the (2-2)th inspection pattern IP2-2 may partially overlap in a plan view. The (1-2)th inspection pattern IP1-2 may be a pattern for confirming alignment of the (1-2)th light emitting layer EL1-2, and the (2-2)th inspection pattern IP2-2 may be a pattern for confirming alignment of the (2-2)th light emitting layer EL2-2. For example, the (1-2)th inspection pattern IP1-2 may be utilized to determine if the (1-2)th light emitting layer EL1-2 is deposited in the desired location. In other words, by measuring the position of the (1-2)th inspection pattern IP1-2, it can be assessed whether the (1-2)th light emitting layer EL1-2 is deposited in the desired location. Similarly, the (2-2)th inspection pattern IP2-2 may be utilized to determine if the (2-2)th light emitting layer EL2-2 is deposited in the desired location. In other words, by measuring the position of the (2-2)th inspection pattern IP2-2, it can be assessed whether the (2-2)th light emitting layer EL2-2 is deposited in the desired location. In an embodiment, the (1-2)th inspection pattern IP1-2 may include the same material as the (1-2)th light emitting layer EL1-2, and the (2-2)th inspection pattern IP2-2 may include the same material as the (2-2)th light emitting layer EL2-2. In an embodiment, the (1-2)th inspection pattern IP1-2 and the (1-2)th light emitting layer EL1-2 may be consisted of the same material, and the (2-2)th inspection pattern IP2-2 and the (2-2)th light emitting layer EL2-2 may be consisted of the same material.

The third inspection array IPA3 may be disposed in the non-display area NDA to confirm alignment of a light emitting layer of the third light emitting element LE3. For example, the third inspection array IPA3 may be utilized to determine if the light emitting layer of the third light emitting element LE3 is deposited in the desired location. In other words, by measuring the position of the third inspection array IPA3, it can be assessed whether the light emitting layer is deposited in the desired location. The third inspection array IPA3 may include the same material as the light emitting layer of the third light emitting element LE3. In an embodiment, the third inspection array IPA3 and the light emitting layer of the third light emitting element LE3 may be consisted of the same material.

The third inspection array IPA3 may include the (1-3)th inspection pattern IP1-3 and the (2-3)th inspection pattern IP2-3 disposed on the (1-3)th inspection pattern IP1-3. The (1-3)th inspection pattern IP1-3 and the (2-3)th inspection pattern IP2-3 may overlap in a plan view. For example, the (1-3)th inspection pattern IP1-3 and the (2-3)th inspection pattern IP2-3 may partially overlap in a plan view. The (1-3)th inspection pattern IP1-3 may be a pattern for confirming alignment of the (1-3)th light emitting layer EL1-3, and the (2-3)th inspection pattern IP2-3 may be a pattern for confirming alignment of the (2-3)th light emitting layer EL2-3. For example, the (1-3)th inspection pattern IP1-3 may be utilized to determine if the (1-3)th light emitting layer EL1-3 is deposited in the desired location. In other words, by measuring the position of the (1-3)th inspection pattern IP1-3, it can be assessed whether the (1-3)th light emitting layer EL1-3 is deposited in the desired location. Similarly, the (2-3)th inspection pattern IP2-3 may be utilized to determine if the (2-3)th light emitting layer EL2-3 is deposited in the desired location. In other words, by measuring the position of the (2-3)th inspection pattern IP2-3, it can be assessed whether the (2-3)th light emitting layer EL2-3 is deposited in the desired location. In an embodiment, the (1-3)th inspection pattern IP1-3 may include the same material as the (1-3)th light emitting layer EL1-3, and the (2-3)th inspection pattern IP2-3 may include the same material as the (2-3)th light emitting layer EL2-3. In an embodiment, the (1-3)th inspection pattern IP1-3 and the (1-3)th light emitting layer EL1-3 may be consisted of the same material, and the (2-3)th inspection pattern IP2-3 and the (2-3) the light emitting layer EL2-3 may be consisted of the same material.

The first, second, and third inspection arrays IPA1, IPA2, and IPA3 may have different shapes or sizes from the first, second, and third light emitting elements LE1, LE2, and LE3, or may have the same shape or size as the first, second, and third light emitting elements LE1, LE2, and LE3. Although FIG. 3 illustrates that each of the first, second, and third inspection arrays IPA1, IPA2, and IPA3 has a circular planar shape, the present disclosure is not limited thereto.

The alignment pattern AP may include a first alignment pattern AP1, a second alignment pattern AP2, and a third alignment pattern AP3.

The first and second alignment patterns AP1 and AP2 may be disposed in the non-display area NDA to confirm alignment of the inspection array IPA. The first alignment pattern AP1 may be adjacent to the inspection array IPA in the first direction DR1, and the second alignment pattern AP2 may be adjacent to the inspection array IPA in the second direction DR2. For example, the first alignment pattern AP1 may be a pattern for confirming the alignment of the inspection array IPA in the first direction DR1, and the second alignment pattern AP2 may be a pattern for confirming the alignment of the inspection array IPA in the second direction DR2. For example, the first alignment pattern AP1 may be arranged with the first, second, and third inspection arrays IPA1, IPA2, and IPA3 along a straight line extending in the first direction DR1, and the second alignment pattern AP2 may be arranged with each of the first, second, and third inspection arrays IPA1, IPA2, and IPA3 along the second direction DR2. For the simplicity of description, in FIG. 3, three inspection arrays IPA1, IPA2, and IP3 and three second alignment patterns AP2 are disposed in the area A of FIG. 1. In an embodiment, the first inspection array IPA1 and one of the three second alignment patterns AP2 may be arranged in a first straight line extending in the second direction DR2, the second inspection array IPA2 and one of the three second alignment patterns AP2 may be arranged in a second straight line extending in the second direction DR2, and the third inspection array IPA3 and one of the three second alignment patterns AP2 may be arranged in a third straight line extending in the second direction DR2. The first to third straight lines are spaced apart from each other in the first direction DR1.

The third alignment pattern AP3 may be a pattern for confirming alignment of the substrate SUB. For example, the third alignment pattern AP3 may be a pattern for confirming alignment with a mask used for forming a specific layer, but the present disclosure is not limited thereto.

Although FIG. 3 illustrates that each of the first and second alignment patterns AP1 and AP2 has a rectangular planar shape and the third alignment pattern AP3 has a cross-shaped planar shape, the present disclosure is not limited thereto.

The charge generation layer CGL may be disposed on the first inspection pattern IP1 and the alignment pattern AP, and may cover the first inspection pattern IP1 and the alignment pattern AP. The charge generation layer CGL may extend from the display area DA to the non-display area NDA. In an embodiment, the charge generation layer CGL may be disposed between the first inspection pattern IP1 and the second inspection pattern IP2. That is, the (1-1)th, (1-2)th, and (1-3)th inspection patterns IP1-1, IP1-2, and IP1-3 may be spaced apart from the (2-1)th, (2-2)th, and (2-3)th inspection patterns IP2-1, IP2-2, and IP2-3 with the charge generation layer CGL interposed therebetween, respectively.

Although FIG. 4 illustrates that no separate component is disposed between the substrate SUB and the first inspection pattern IP1, the present disclosure is not limited thereto. In an embodiment, another component included in the display device 10 (e.g., the insulating layer included in the circuit layer TL or the like) may be further disposed between the substrate SUB and the first inspection pattern IP1.

In addition, although FIG. 4 illustrates that the charge generation layer CGL is disposed between the first inspection pattern IP1 and the second inspection pattern IP2, the present disclosure is not limited thereto. In an embodiment, another component instead of the charge generation layer CGL may be disposed between the first inspection pattern IP1 and the second inspection pattern IP2, or another component other than the charge generation layer CGL may be further disposed between the first inspection pattern IP1 and the second inspection pattern IP2.

In addition, although FIG. 4 illustrates that the inspection array IPA includes a structure in which two inspection patterns are stacked, the present disclosure is not limited thereto. For another example, the inspection array IPA may include a structure in which one inspection pattern is disposed or three or more inspection patterns are stacked.

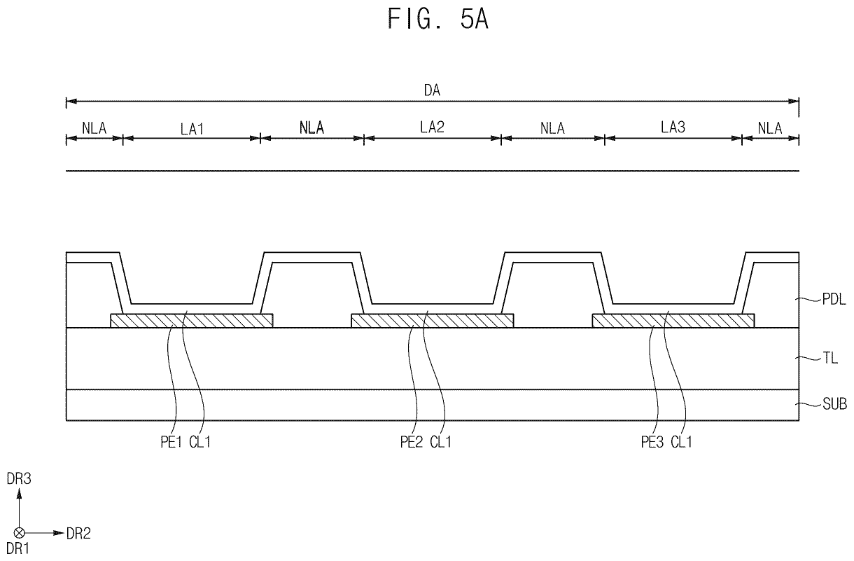

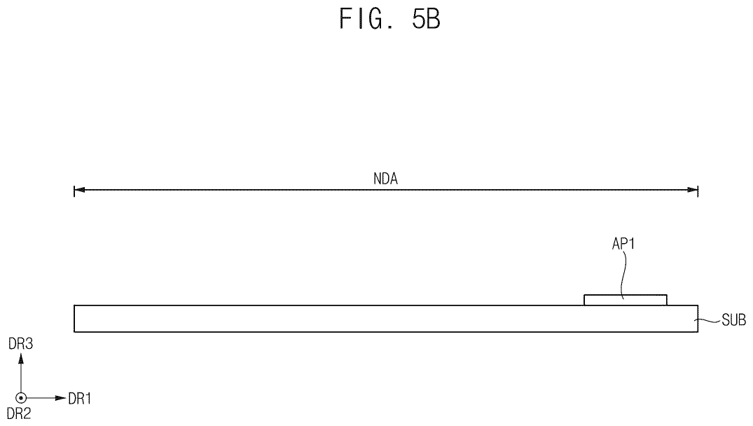

FIGS. 5A, 5B, 6A, 6B, 7A, 7B, 8A, and 8B are views illustrating a method of manufacturing a display device according to an embodiment of the present disclosure.

For example, the method of manufacturing the display device described with reference to FIGS. 5A, 5B, 6A, 6B, 7A, 7B, 8A, and 8B may be a method of manufacturing the display device 10 described with reference to FIGS. 1, 2, 3, and 4. In addition, FIGS. 5A, 5B, 6A, 6B, 7A, 7B, 8A, and 8B may be cross-sectional views illustrating the method of manufacturing the display device 10 corresponding to FIGS. 2 and 4. Hereinafter, redundant descriptions are omitted or simplified.

Referring to FIGS. 5A and 5B, the circuit layer TL, the first, second, and third pixel electrodes PE1, PE2, and PE3, the pixel defining layer PDL, and the first common layer CL1 may be sequentially formed in the display area DA on the substrate SUB, and an alignment pattern (e.g., the first alignment pattern AP1) may be formed in the non-display area NDA on the substrate SUB.

The first, second, and third pixel electrodes PE1, PE2, and PE3 may be formed to overlap the first, second, and third light emitting areas LA1, LA2, and LA3 in a plan view, respectively, and the pixel defining layer PDL may be formed to overlap the non-light emitting area NLA in a plan view.

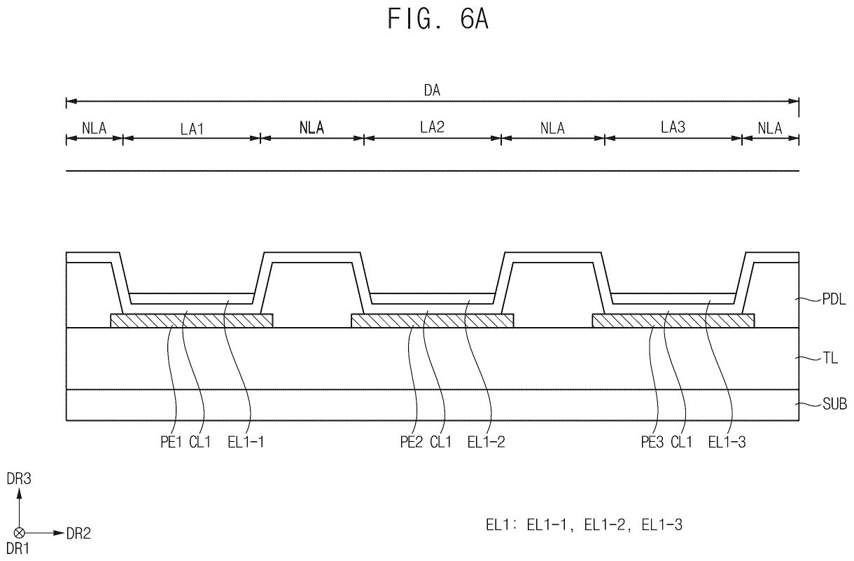

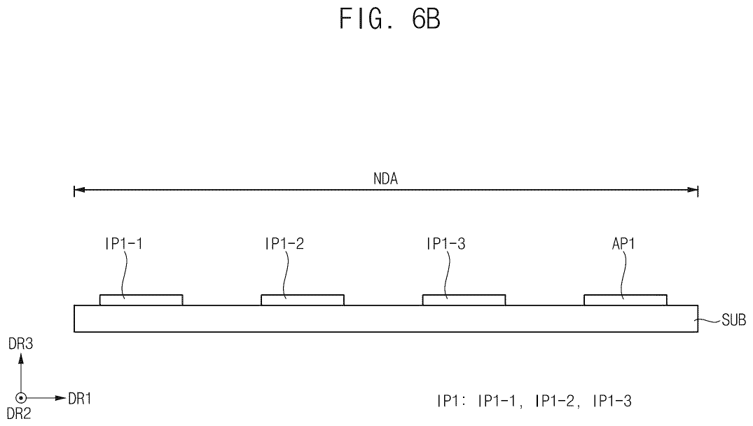

Referring to FIGS. 6A and 6B, the first light emitting layer EL1 may be formed in the display area DA on the first common layer CL1, and the first inspection pattern IP1 may be formed in the non-display area NDA on the substrate SUB.

The first light emitting layer EL1 may include the (1-1)th, (1-2)th, and (1-3)th light emitting layers EL1-1, EL1-2, and EL1-3, and the (1-1)th, (1-2)th, and (1-3)th light emitting layers EL1-1, EL1-2, and EL1-3 may be formed to overlap the first, second, and third light emitting areas LA1, LA2, and LA3 in a plan view, respectively.

The first inspection pattern IP1 may include the (1-1)th, (1-2)th, and (1-3)th inspection patterns IP1-1, IP1-2, and IP1-3, and the (1-1)th, (1-2)th, and (1-3)th inspection patterns IP1-1, IP1-2, and IP1-3 may be formed along the first direction DR1.

The (1-1)th light emitting layer EL1-1 and the (1-1)th inspection pattern IP1-1 may be formed of the same material, and may be formed through the same process. For example, the (1-1)th light emitting layer EL1-1 and the (1-1)th inspection pattern IP1-1 may be formed of a material that emits the first light, and may be formed using a first mask (e.g., a fine metal mask (FMM)) that defines an opening corresponding to the (1-1)th light emitting layer EL1-1 and the (1-1)th inspection pattern IP1-1.

The (1-2)th light emitting layer EL1-2 and the (1-2)th inspection pattern IP1-2 may be formed of the same material, and may be formed through the same process. For example, the (1-2)th light emitting layer EL1-2 and the (1-2)th inspection pattern IP1-2 may be formed of a material that emits the second light, and may be formed using a second mask (e.g., an FMM) that defines an opening corresponding to the (1-2)th light emitting layer EL1-2 and the (1-2)th inspection pattern IP1-2.

The (1-3)th light emitting layer EL1-3 and the (1-3)th inspection pattern IP1-3 may be formed of the same material, and may be formed through the same process. For example, the (1-3)th light emitting layer EL1-3 and the (1-3)th inspection pattern IP1-3 may be formed of a material that emits the third light, and may be formed using a third mask (e.g., an FMM) that defines an opening corresponding to the (1-3)th light emitting layer EL1-3 and the (1-3)th inspection pattern IP1-3.

For example, the (1-1)th light emitting layer EL1-1 and the (1-1)th inspection pattern IP1-1 may be formed through a deposition process using the first mask, thereafter, the (1-3)th light emitting layer EL1-3 and the (1-3)th inspection pattern IP1-3 may be formed through a deposition process using the third mask, and thereafter, the (1-2)th light emitting layer EL1-2 and the (1-2)th inspection pattern IP1-2 may be formed through a deposition process using the second mask. However, the present disclosure is not limited thereto, and the order in which the (1-1)th, (1-2)th, and (1-3)th light emitting layers EL1-1, EL1-2, and EL1-3 and the (1-1)th, (1-2)th, and (1-3)th inspection patterns IP1-1, IP1-2, and IP1-3 are formed may be variously modified.

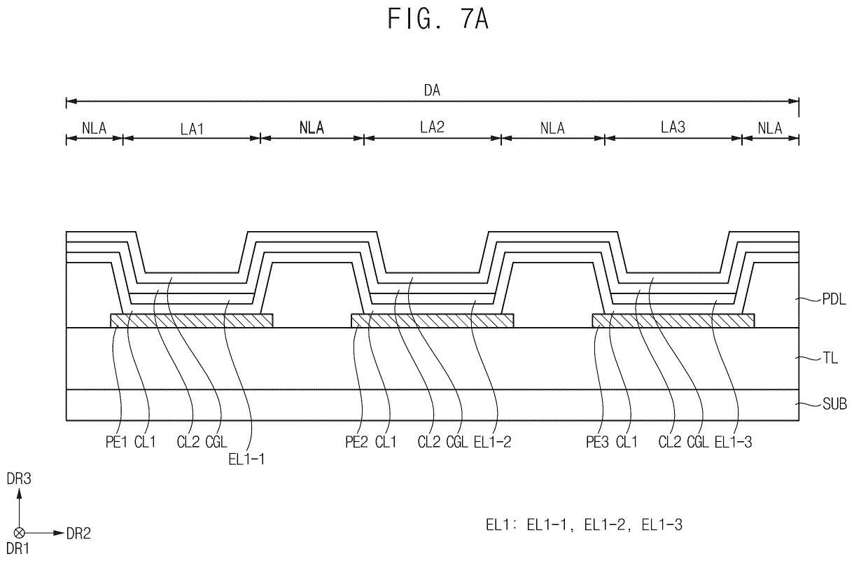

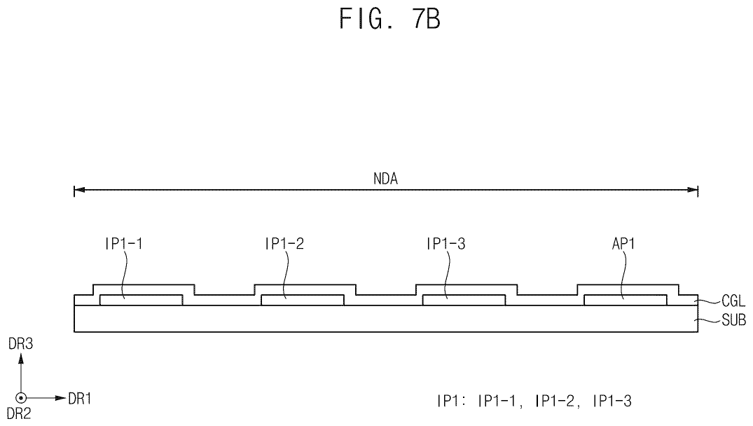

Referring to FIGS. 7A and 7B, the second common layer CL2 and the charge generation layer CGL may be sequentially formed in the display area DA on the first light emitting layer EL1. In an embodiment, the second common layer CL2 may be formed in the display area DA, and the charge generation layer CGL may be formed in the display area DA and the non-display area NDA. In the non-display area NDA, the charge generation layer CGL may be disposed on the first inspection pattern IP1 and the alignment pattern (e.g., the first alignment pattern AP1).

The charge generation layer CGL may extend from the display area DA to the non-display area NDA. For example, the charge generation layer CGL may be formed using a mask (e.g., an open mask) that defines an opening corresponding to the display area DA and the non-display area NDA. For example, the opening of the open mask may expose regions of the resulting structure of FIGS. 6A and 6B corresponding to the display area DA and the non-display area NDA.

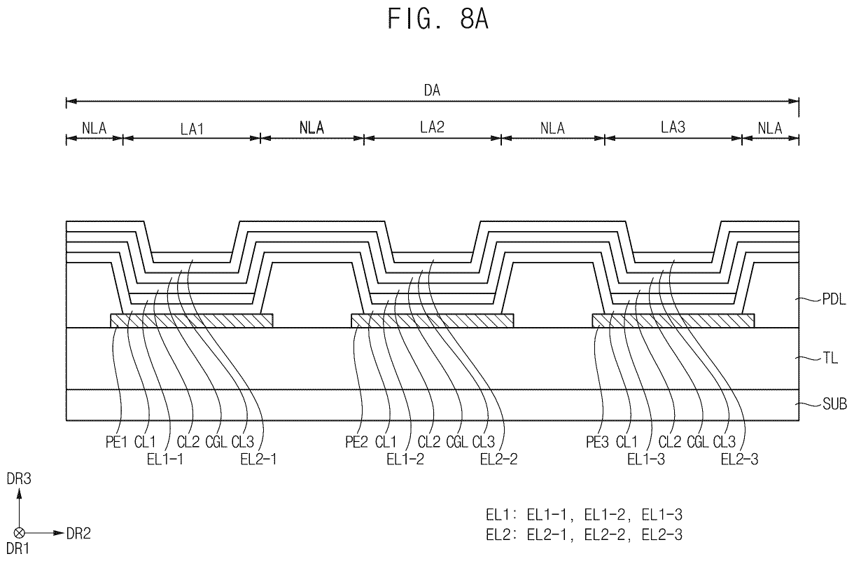

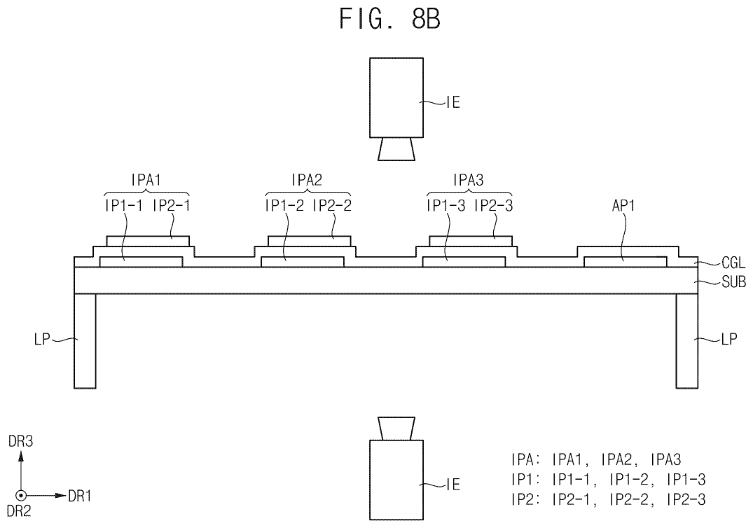

Referring to FIGS. 8A and 8B, the third common layer CL3 and the second light emitting layer EL2 may be sequentially formed in the display area DA on the charge generation layer CGL, and the second inspection pattern IP2 may be formed in the non-display area NDA on the charge generation layer CGL. Accordingly, the first, second, and third inspection arrays IPA1, IPA2, and IPA3 may be formed in the non-display area NDA on the substrate SUB.

The second light emitting layer EL2 may include the (2-1)th, (2-2)th, and (2-3)th light emitting layers EL2-1, EL2-2, and EL2-3, and the (2-1)th, (2-2)th, and (2-3)th light emitting layers EL2-1, EL2-2, and EL2-3 may be formed to overlap the first, second, and third light emitting areas LA1, LA2, and LA3 in a plan view, respectively. In addition, the (2-1)th, (2-2)th, and (2-3)th light emitting layers EL2-1, EL2-2, and EL2-3 may be formed to overlap the (1-1)th, (1-2)th, and (1-3)th light emitting layers EL1-1, EL1-2, and EL1-3 in a plan view, respectively. In an embodiment, the (2-1)th, (2-2)th, and (2-3)th light emitting layers EL2-1, EL2-2, and EL2-3 may be formed of or may be consisted of the same material as the (1-1)th, (1-2)th, and (1-3)th light emitting layers EL1-1, EL1-2, and EL1-3, respectively. In an embodiment, the (2-1)th, (2-2)th, and (2-3)th light emitting layers EL2-1, EL2-2, and EL2-3 may be formed of different materials from the (1-1)th, (1-2)th, and (1-3)th light emitting layers EL1-1, EL1-2, and EL1-3, respectively.

The second inspection pattern IP2 may include the (2-1)th, (2-2)th, and (2-3)th inspection patterns IP2-1, IP2-2, and IP2-3, and the (2-1)th, (2-2)th, and (2-3)th inspection patterns IP2-1, IP2-2, and IP2-3 may be formed along the first direction DR1. In addition, the (2-1)th, (2-2)th, and (2-3)th inspection patterns IP2-1, IP2-2, and IP2-3 may be formed to overlap the (1-1)th, (1-2)th, and (1-3)th inspection patterns IP1-1, IP1-2, and IP1-3 in a plan view, respectively. For example, the (2-1)th, (2-2)th, and (2-3)th inspection patterns IP2-1, IP2-2, and IP2-3 may be formed to partially overlap the (1-1)th, (1-2)th, and (1-3)th inspection patterns IP1-1, IP1-2, and IP1-3 in a plan view, respectively.

In an embodiment, the (2-1)th, (2-2)th, and (2-3)th inspection patterns IP2-1, IP2-2, and IP2-3 may be formed of or may be consisted of the same material as the (1-1)th, (1-2)th, and (1-3)th inspection patterns IP1-1, IP1-2, and IP1-3, respectively. In an embodiment, the (2-1)th, (2-2)th, and (2-3)th inspection patterns IP2-1, IP2-2, and IP2-3 may be formed of different materials from the (1-1)th, (1-2)th, and (1-3)th inspection patterns IP1-1, IP1-2, and IP1-3, respectively.

The (2-1)th light emitting layer EL2-1 and the (2-1)th inspection pattern IP2-1 may be formed of or may be consisted of the same material, and may be formed through the same process. In an embodiment, the (2-1)th light emitting layer EL2-1 and the (2-1)th inspection pattern IP2-1 may be formed by using the first mask used to form the (1-1)th light emitting layer EL1-1 and the (1-1)th inspection pattern IP1-1. That is, the (1-1)th and (2-1)th light emitting layers EL1-1 and EL2-1 and the (1-1)th and (2-1)th inspection patterns IP1-1 and IP2-1 may be formed by using the same mask. For example, the (2-1)th light emitting layer EL2-1 and the (2-1)th inspection pattern IP2-1 may be formed of or may be consisted of a material that emits the first light, and may be formed by using the first mask that defines an opening corresponding to the (2-1)th light emitting layer EL2-1 and the (2-1)th inspection pattern IP2-1.

The (2-2)th light emitting layer EL2-2 and the (2-2)th inspection pattern IP2-2 may be formed of or may be consisted of the same material, and may be formed through the same process.

In an embodiment, the (2-2)th light emitting layer EL2-2 and the (2-2)th inspection pattern IP2-2 may be formed using the second mask used to form the (1-2)th light emitting layer EL1-2 and the (1-2)th inspection pattern IP1-2. That is, the (1-2)th and (2-2)th light emitting layers EL1-2 and EL2-2 and the (1-2)th and (2-2)th inspection patterns IP1-2 and IP2-2 may be formed using the same mask. For example, the (2-2)th light emitting layer EL2-2 and the (2-2)th inspection pattern IP2-2 may be formed of or may be consisted of a material that emits the second light, and may be formed using the second mask that defines an opening corresponding to the (2-2)th light emitting layer EL2-2 and the (2-2)th inspection pattern IP2-2.

The (2-3)th light emitting layer EL2-3 and the (2-3)th inspection pattern IP2-3 may be formed of or may be consisted of the same material, and may be formed through the same process. In an embodiment, the (2-3)th light emitting layer EL2-3 and the (2-3)th inspection pattern IP2-3 may be formed using the third mask used to form the (1-3)th light emitting layer EL1-3 and the (1-3)th inspection pattern IP1-3. That is, the (1-3)th and (2-3)th light emitting layers EL1-3 and EL2-3, and the (1-3)th and (2-3)th inspection patterns IP1-3 and IP2-3 may be formed using the same mask. For example, the (2-3)th light emitting layer EL2-3 and the (2-3)th inspection pattern IP2-3 may be formed of or may be consisted of a material that emits the third light, and may be formed using the third mask that defines an opening corresponding to the (2-3)th light emitting layer EL2-3 and the (2-3)th inspection pattern IP2-3.

For example, the (2-3)th light emitting layer EL2-3 and the (2-3)th inspection pattern IP2-3 may be formed through a deposition process using the third mask, thereafter, the (2-2)th light emitting layer EL2-2 and the (2-2)th inspection pattern IP2-2 may be formed through a deposition process using the second mask, and thereafter, the (2-1)th light emitting layer EL2-1 and the (2-1)th inspection pattern IP2-1 may be formed through a deposition process using the first mask. However, the present disclosure is not limited thereto, and the order in which the (2-1)th, (2-2)th, and (2-3)th light emitting layers EL2-1, EL2-2, and EL2-3 and the (2-1)th, (2-2)th, and (2-3)th inspection patterns IP2-1, IP2-2, and IP2-3 are formed may be variously modified.

After the second light emitting layer EL2 and the second inspection pattern IP2 are formed, the alignment of the first light emitting layer EL1 may be confirmed through the first inspection pattern IP1, and the alignment of the second light emitting layer EL2 may be confirmed through the second inspection pattern IP2. For example, the substrate SUB may be transferred in the third direction DR3 using a lift pin LP, and the first inspection pattern IP1 and the second inspection pattern IP2 may be simultaneously measured through an inspection equipment IE.

Since the first and second inspection patterns IP1 and IP2 are spaced apart from each other with the charge generation layer CGL interposed therebetween, the first and second inspection patterns IP1 and IP2 overlapping in a plan view may be respectively measured through the inspection equipment IE. For example, the inspection equipment IE below the substrate in the third direction DR3 may measure the first inspection pattern IP1, and the inspection equipment IE above the substrate SUB in a direction opposite to the third direction DR3 may measure the second inspection pattern IP2. For example, the inspection equipment IE may be various types of equipment that measures the first and second inspection patterns IP1 and IP2, such as a polarizing microscope, an imaging ellipsometer, or the like. For example, the inspection equipment IE may measure the positions and alignments of the first and second inspection patterns IP1 and IP2 to assess whether the first and second inspection patterns IP1 and IP2 are deposited in the desired locations.

By measuring the first inspection pattern IP1 formed through the same process as the first light emitting layer EL1, shift, contraction, expansion, or the like of the first, second, and third masks may be confirmed and the alignment of the first light emitting layer EL1 may be confirmed. In addition, by measuring the second inspection pattern IP2 formed through the same process as the second light emitting layer EL2, shift, contraction, expansion, or the like of the first, second, and third masks may be confirmed and the alignment of the second light emitting layer EL2 may be confirmed. That is, the alignment of the (1-1)th, (1-2)th, and (1-3)th light emitting layers EL1-1, EL1-2, and EL1-3 may be confirmed by measuring the (1-1)th, (1-2)th, and (1-3)th inspection patterns IP1-1, IP2-2, and IP2-3, respectively, and the alignment of the (2-1)th, (2-2)th, and (2-3)th light emitting layers EL2-1, EL2-2, and EL2-3 may be confirmed by measuring the (2-1)th, (2-2)th, and (2-3)th inspection patterns IP2-1, IP2-2, and IP2-3, respectively.

Referring back to FIGS. 1, 2, and 4, the fourth common layer CL4, the common electrode CE, and the encapsulation layer TFE may be sequentially formed in the display area DA on the second light emitting layer EL2. Accordingly, the display device 10 including the first and second light emitting layers EL1 and EL2 overlapping in a plan view in the display area DA and the first and second inspection patterns IP1 and IP2 overlapping in a plan view in the non-display area NDA may be manufactured.

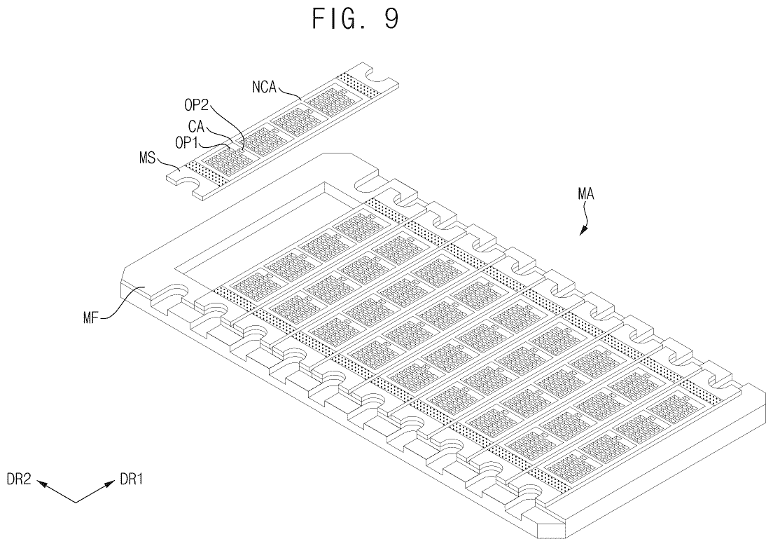

FIG. 9 is a perspective view schematically illustrating a mask used in a method of manufacturing a display device according to an embodiment of the present disclosure.

For example, a mask MA described with reference to FIG. 9 may be a mask used in the method of manufacturing the display device 10 described with reference to FIGS. 5A, 5B, 6A, 6B, 7A, 7B, 8A, and 8B. That is, the mask MA may correspond to the first, second, and third masks used to form the first and second light emitting layers EL1 and EL2 and the first and second inspection patterns IP1 and IP2 included in the display device 10, respectively.

Referring to FIG. 9, the mask MA may include a mask frame MF and at least one mask sheet MS.

The mask frame MF may have one or more frames defining an opening of a central portion. When the mask frame MF includes a plurality of frames, the frames may be connected to each other to form one mask frame.

The mask sheet MS may be disposed on the mask frame MF. The mask sheet MS may extend in the first direction DR1, and when a plurality of mask sheets MS are provided, the mask sheets MS may be arranged along the second direction DR2. The mask sheet MS may cover the opening of the mask frame MF.

The mask sheet MS may include a cell area CA and a peripheral area NCA. The cell area CA may correspond to a deposition area in which a deposition material is deposited on a target substrate, and the peripheral area NCA may correspond to a non-deposition area in which the deposition material is not deposited on the target substrate. First openings OP1 and a second opening OP2 may be defined in the cell area CA, and the peripheral area NCA may surround the cell area CA.

The first openings OP1 may be disposed to be spaced apart from each other, and may form a predetermined pattern. For example, the first openings OP1 may be disposed along the first direction DR1 or the second direction DR2. The first openings OP1 may correspond to an area in which the first and second light emitting layers EL1 and EL2 are formed in the display area DA on the substrate SUB. The first openings OP1 may correspond to the first, second, and third light emitting areas LA1, LA2 and LA3 on the substrate SUB.

The second opening OP2 may be disposed to be spaced apart from the first openings OP1. The second opening OP2 may correspond to an area in which the first and second inspection patterns IP1 and IP2 are formed in the non-display area NDA on the substrate SUB.

The (1-1)th, (1-2)th, and (1-3)th light emitting layers EL1-1, EL1-2, and EL1-3, and the (1-1)th, (1-2)th, and (1-3)th inspection patterns IP1-1, IP1-2, and IP1-3 may be formed corresponding to the first openings OP1 and the second opening OP2, respectively, using the mask MA, and the (2-1)th, (2-2)th, and (2-3)th light emitting layers EL2-1, EL2-2, and the (2-1)th, (2-2)th, and (2-3)th inspection patterns IP2-1, IP2-2, and IP2-3 may be formed corresponding to the first openings OP1 and the second opening OP2, respectively, using the mask MA.

In the display device 10 and the method of manufacturing the same according to an embodiment of the present disclosure, the first and second light emitting layers EL1 and EL2 and the first and second inspection patterns IP1 and IP2 used to confirm the alignment of the first and second light emitting layers EL1 and EL2, respectively, may be formed by using the same mask. Since different layers (e.g., the (1-1)th light emitting layer EL1-1 and the (2-1)th light emitting layer EL2-1) may be formed by using one mask, a burden on mask management, design, or the like may be minimized, and an area in which the first and second inspection patterns IP1 and IP2 are disposed in the non-display area NDA may be relatively reduced. In addition, since the alignment of the first and second light emitting layers EL1 and EL2 may be inspected by measuring the first and second inspection patterns IP1 and IP2, respectively, using the inspection equipment IE, even if different layers overlap each other in a plan view, the alignment of the layers may be confirmed, respectively.

The display device 10 according to an embodiment of the present disclosure may be applied to various electronic devices. An electronic device according to an embodiment of the present disclosure may include the display device 10 described above, and may further include a module or device having additional functions in addition to the display device 10.

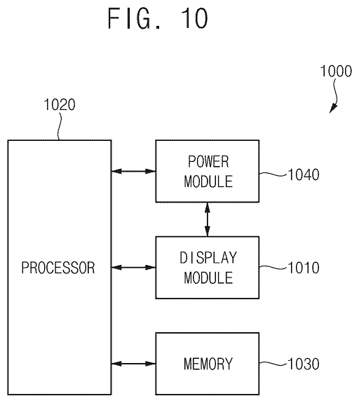

FIG. 10 is a block diagram illustrating an electronic device according to an embodiment of the present disclosure.

Referring to FIG. 10, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module that converts power supplied by the power supply module to generate power necessary for an operation of the electronic device 1000.

At least one of the components of the electronic device 1000 described above may be included in the display device according to an embodiment described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

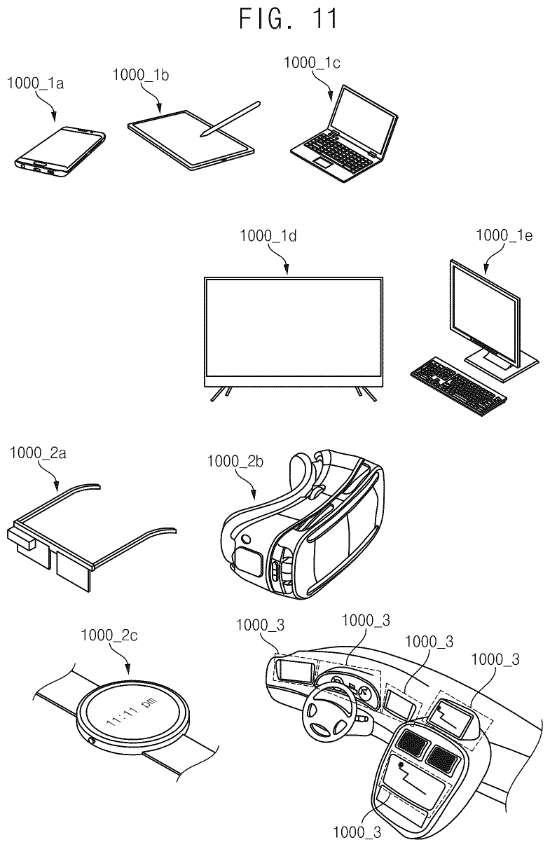

FIG. 11 is a schematic view illustrating electronic devices according to embodiments of the present disclosure.

Referring to FIG. 11, various electronic devices to which the display device according to an embodiment of the present disclosure is applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate including a display area and a non-display area adjacent to the display area;
a light emitting element disposed in the display area of the substrate and including a first light emitting layer and a second light emitting layer disposed on the first light emitting layer; and
an inspection array disposed in the non-display area of the substrate and including a first inspection pattern and a second inspection pattern disposed on the first inspection pattern.

2. The display device of claim 1,
wherein the first light emitting layer and the first inspection pattern include a same material, and
wherein the second light emitting layer and the second inspection pattern include a same material.

3. The display device of claim 1,
wherein the first light emitting layer and the second light emitting layer overlap in a plan view.

4. The display device of claim 1,
wherein the first inspection pattern and the second inspection pattern overlap in a plan view.

5. The display device of claim 1,
wherein the first light emitting layer and the second light emitting layer include a same material.

6. The display device of claim 1, further comprising:
a charge generation layer disposed between the first light emitting layer and the second light emitting layer and between the first inspection pattern and the second inspection pattern,
wherein the charge generation layer includes a first semiconductor layer doped with n-type dopants and a second semiconductor layer doped with p-type dopants.

7. The display device of claim 6,
wherein the charge generation layer extends from the display area to the non-display area.

8. The display device of claim 1,
wherein the light emitting element includes:
a first light emitting element that emits first light and includes a first first light emitting layer and a first second light emitting layer disposed on the first first light emitting layer;
a second light emitting element that emits second light and includes a second first light emitting layer and a second second light emitting layer disposed on the second first light emitting layer; and
a third light emitting element that emits third light and includes a third first light emitting layer and a third second light emitting layer disposed on the third first light emitting layer.

9. The display device of claim 8, wherein the inspection array includes:
a first inspection array including:
a first first inspection pattern including a same material as the first first light emitting layer, and
a first second inspection pattern disposed on the first first inspection pattern and including a same material as the first second light emitting layer;
a second inspection array including:
a second first inspection pattern including a same material as the second first light emitting layer, and
a second second inspection pattern disposed on the second first inspection pattern and including a same material as the second second light emitting layer; and
a third inspection array including:
a third first inspection pattern including a same material as the third first light emitting layer, and
a third second inspection pattern disposed on the third first inspection pattern and including a same material as the third second light emitting layer.

10. The display device of claim 9,
wherein the second inspection array is adjacent to the first inspection array in one direction, and
wherein the third inspection array is adjacent to the second inspection array in the one direction.

11. A method of manufacturing a display device comprising:
forming a first light emitting layer in a display area on a substrate and a first inspection pattern in a non-display area on the substrate using a plurality of masks, wherein the non-display area is adjacent to the display area; and
forming a second light emitting layer on the first light emitting layer and a second inspection pattern on the first inspection pattern using the plurality of masks.

12. The method of claim 11,
wherein the first light emitting layer and the first inspection pattern are formed of a same material, and
wherein the second light emitting layer and the second inspection pattern are formed of a same material.

13. The method of claim 11,
wherein the first light emitting layer and the second light emitting layer are formed to overlap in a plan view, and
wherein the first inspection pattern and the second inspection pattern are formed to overlap in the plan view.

14. The method of claim 11,
wherein the first light emitting layer and the second light emitting layer are formed of a same material.

15. The method of claim 11, further comprising:
after the forming of the first light emitting layer and the first inspection pattern and before the forming of the second light emitting layer and the second inspection pattern, forming a charge generation layer on the first light emitting layer and the first inspection pattern using an open mask defining an opening corresponding to the display area and the non-display area.

16. The method of claim 11, further comprising:
after the forming of the second light emitting layer and the second inspection pattern, measuring the first inspection pattern to confirm alignment of the first light emitting layer and measuring the second inspection pattern to confirm alignment of the second light emitting layer.

17. The method of claim 11,
wherein the forming of the first light emitting layer and the first inspection pattern includes:
forming a first first light emitting layer and a first first inspection pattern using a first mask among the plurality of masks;
forming a second first light emitting layer and a second first inspection pattern using a second mask among the plurality of masks; and
forming a third first light emitting layer and a third first inspection pattern using a third mask among the plurality of masks.

18. The method of claim 17,
wherein the first first light emitting layer and the first first inspection pattern are formed of a material that emits first light,
wherein the second first light emitting layer and the second first inspection pattern are formed of a material that emits second light, and
wherein the third first light emitting layer and the third first inspection pattern are formed of a material that emits third light.

19. The method of claim 17,
wherein the forming of the second light emitting layer and the second inspection pattern includes:
forming a first second light emitting layer on the first first light emitting layer and a first second inspection pattern on the first first inspection pattern using the first mask;
forming a second second light emitting layer on the second first light emitting layer and a second second inspection pattern on the second first inspection pattern using the second mask; and
forming a third second light emitting layer on the third first light emitting layer and a third second inspection pattern on the third first inspection pattern using the third mask.

20. The method of claim 19,
wherein the first second light emitting layer and the first second inspection pattern are formed of a material that emits first light,
wherein the second second light emitting layer and the second second inspection pattern are formed of a material that emits second light, and
wherein the third second light emitting layer and the third second inspection pattern are formed of a material that emits third light.

21. An electronic device comprising:
a display device; and
a power module that supplies power to the display device,
wherein the display device includes:
a substrate including a display area and a non-display area adjacent to the display area;
a light emitting element disposed in the display area of the substrate and including a first light emitting layer and a second light emitting layer disposed on the first light emitting layer; and
an inspection array disposed in the non-display area of the substrate and including a first inspection pattern and a second inspection pattern disposed on the first inspection pattern.
